(19) United States
(12) Patent Application Publication
(10) Pub. No.: US 2017/0288117 A1
(43) Pub. Date: Oct. 5, 2017

(54) THERMOELECTRIC MODULE AND METHOD FOR MANUFACTURING THE SAME

(71) Applicant: Hyundai Motor Company, Seoul (KR)

(72) Inventors: Mi Yeon SONG, Seoul (KR); Sung Geun PARK, Seoul (KR); Eun Yeong LEE, Seoul (KR); Sang Hak KIM, Seoul (KR)

(73) Assignee: Hyundai Motor Company, Seoul (KR)

(21) Appl. No.: 15/358,576

(22) Filed: Nov. 22, 2016

(30) Foreign Application Priority Data
Mar. 30, 2016 (KR) 10-2016-0038028

(51) Int. Cl. H01L 35/32; H01L 35/34

(52) U.S. Cl. CPC H01L 35/32; H01L 35/34

(57) ABSTRACT

A thermoelectric module may include a plurality of P-type thermoelectric elements formed of an organic material, a plurality of N-type thermoelectric elements disposed to be parallel between the plurality of P-type thermoelectric elements and formed of a metal, a first electrode part configured to connect an upper end of each of the plurality of N-type thermoelectric elements and an upper end of each of the plurality of P-type thermoelectric elements, and a second electrode part configured to connect a lower end of each of the N-type thermoelectric elements and a lower end of each of the plurality of P-type thermoelectric elements, wherein the first electrode part, the second electrode part, and the plurality of N-type thermoelectric elements are formed of a metal.

### CROSS-REFERENCE TO RELATED APPLICATION

The present application is based on and claims the benefit of priority to Korean Patent Application No. 10-2016-0038028, filed on Mar. 30, 2016, in the Korean Intellectual Property Office, the entire contents of which is incorporated herein for all purposes by this reference.

### FIELD OF THE INVENTION

The present invention relates to a thermoelectric module, and more particularly, to a thermoelectric module having enhanced impact resistance and thermal shock resistance by employing a lightweight, flexible organic thermoelectric element, thus being easily applied to various systems and having significantly enhanced thermoelectric power generating performance, and a method for manufacturing the same.

### BACKGROUND

As known, a thermoelectric module may generate power using the Seeback effect of producing a thermoelectromotive force due to a temperature difference between both sides thereof. Waste heat of a vehicle may be effectively utilized by applying such a thermoelectric module to the vehicle.

In a related art thermoelectric module, one side thereof is installed in an exhaust system component (an exhaust pipe, an exhaust manifold, etc.) of a vehicle discharging exhaust heat having a high temperature, and a water cooling type cooling system is installed on the other side of the thermoelectric module in order to secure a temperature difference.

As a thermoelectric element of a thermoelectric module applied to a vehicle, an inorganic BiTe-based thermoelectric element is largely used.

However, the BiTe-based thermoelectric element has low impact resistance and is vulnerable to thermal shock, having low durability, is high in price, and is heavy in weight, increasing a weight of an overall thermoelectric power generating system.

Recently, research and development have been made on a thermoelectric module employing an organic thermoelectric element, and since the organic thermoelectric element is low in price, lightweight, and flexible, compared with an non-organic thermoelectric element, and thus, there is no structural restriction when the organic thermoelectric element is applied to a vehicle.

However, the related art organic thermoelectric element is formed to be thin, having a thickness in unit of nanometers, there is a limitation in generating a temperature difference in a vertical direction (a temperature difference between a hot side and a cold side).

Also, the related art organic thermoelectric element has various problems in that a partition formed of an insulating material should be formed between a P-type thermoelectric element and an N-type thermoelectric element during a manufacturing process, contamination is anticipated due to a solvent for removing the partition, a process time is lengthened, and process cost is increased.

The information disclosed in this Background of the Invention section is only for enhancement of understanding of the general background of the invention and should not be taken as an acknowledgement or any form of suggestion that this information forms the prior art already known to a person skilled in the art.

### BRIEF SUMMARY

Various aspects of the present invention are directed to providing a thermoelectric module which simplifies a manufacturing process to reduce manufacturing cost and has a thickness ranging from a few to hundreds of micrometers to stably maintain a temperature difference in a vertical direction (a temperature different between a hot side and a cold side), as well as a temperature difference in a horizontal direction, thus enhancing thermoelectric power generation performance, and a method for manufacturing the same.

According to an exemplary embodiment of the present invention, a thermoelectric module includes: a plurality of P-type thermoelectric elements formed of an organic material; a plurality of N-type thermoelectric elements disposed to be parallel between the plurality of P-type thermoelectric elements and formed of a metal; a first electrode part configured to connect an upper end of each of the plurality of N-type thermoelectric elements and an upper end of each of the plurality of P-type thermoelectric elements; and a second electrode part configured to connect a lower end of each of the N-type thermoelectric elements and a lower end of each of the plurality of P-type thermoelectric elements, wherein the first electrode part, the second electrode part, and the plurality of N-type thermoelectric elements are formed of a metal.

The plurality of P-type thermoelectric elements may be formed of a conductive polymer material.

The plurality of P-type thermoelectric elements may be formed of PEDOT:PSS.

The first electrode part, the second electrode part, and the plurality of N-type thermoelectric elements may be formed as the same body.

The upper end of each of the plurality of N-type thermoelectric elements and the first electrode part may be adhered through a conductive glue interposed therebetween, and the lower end of each of the N-type thermoelectric elements and the second electrode part may be adhered through a conductive glue interposed therebetween.

The plurality of P-type thermoelectric elements and the plurality of N-type thermoelectric elements may be configured to have different areas.

An area of each of the plurality of P-type thermoelectric elements may be greater than an area of each of the plurality of N-type thermoelectric elements.

An area of each of the plurality of N-type thermoelectric elements and an area of each of the plurality of P-type thermoelectric elements may be in the ratio of 1:16 to 300.

An area of each of the plurality of N-type thermoelectric elements and an area of each of the plurality of P-type thermoelectric elements may be in the ratio of 1:150 to 270.

According to another exemplary embodiment of the present invention, a method for manufacturing a thermoelectric module includes: a P-type thermoelectric element formation operation of forming a P-type thermoelectric element in the form of a polymer film by drying a conductive polymer solution; an attaching operation of attaching a plurality of P-type thermoelectric elements to a substrate; and an N-type thermoelectric element connection operation of connecting N-type thermoelectric elements formed of a metal in series between the plurality of P-type thermoelectric elements.

The P-type thermoelectric element formation operation may include: a film formation operation of filling a container with a PEDOT:PSS solution and drying the PEDOT:PSS solution to form a PEDOT:PSS film; a dipping operation of dipping the PEDOT:PSS film in an organic solvent; and a film separation operation of separating the PEDOT:PSS film from the container.

In the dipping operation, the PEDOT:PSS film may be dipped together with the container in the organic solvent, and the organic solvent may be ethylene glycol (EG) or dimehtyl sulfoxide (DMSO).

In the film formation operation, a thickness of each of the plurality of P-type thermoelectric elements may be adjusted by repeatedly filling the container with the PEDOT:PSS solution before the PEDOT:PSS solution is dried.

In the attaching operation, the plurality of P-type thermoelectric elements may be mounted on the substrate and subsequently dried under a high temperature atmosphere to allow the plurality of P-type thermoelectric elements to be attached to the substrate.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a plan view illustrating a thermoelectric module according to various exemplary embodiments of the present invention.

FIG. 2 is a flow chart illustrating a method for manufacturing a thermoelectric module according to various exemplary embodiments of the present invention.

FIG. 3 is a view illustrating a process of filling a container with a conductive polymer solution, in a method for manufacturing a thermoelectric module according to an exemplary embodiment of the present invention.

FIG. 4 is a view illustrating a state in which a conductive polymer solution within a container is dried to form a polymer film within the container, in a method for manufacturing a thermoelectric module according to an exemplary embodiment of the present invention.

FIG. 5 is a view illustrating a process of dipping a polymer film together with a container, in a method for manufacturing a thermoelectric module according to an exemplary embodiment of the present invention.

FIG. 6 is a view illustrating a process of separating a polymer film from the container, in a method for manufacturing a thermoelectric module according to an exemplary embodiment of the present invention.

FIG. 7 is a view illustrating a process of attaching a polymer film to a substrate, in a method for manufacturing a thermoelectric module according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several FIGS. of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

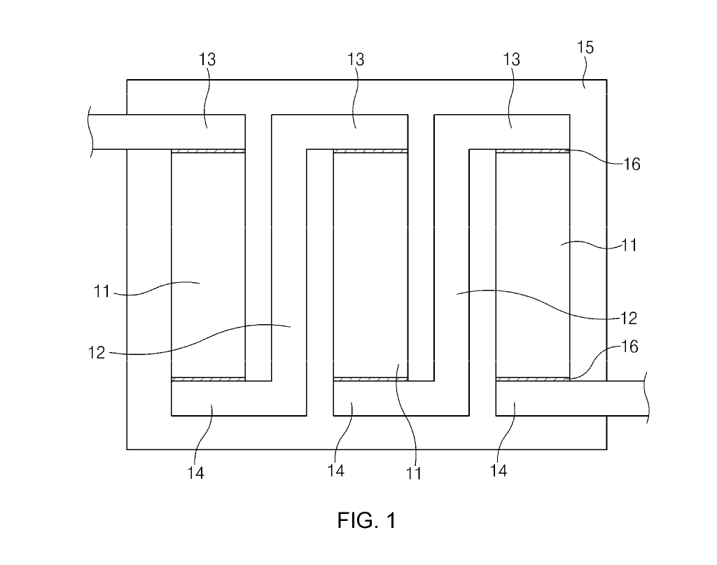

Referring to FIG. 1, a thermoelectric module 10 according to various exemplary embodiments of the present invention may include a plurality of P-type thermoelectric elements 11 formed of an organic material, a plurality of N-type thermoelectric elements 12 positioned to be parallel between the plurality of P-type thermoelectric elements 11, a first electrode part 13 connecting an upper end of the N-type thermoelectric element 12 and an upper end of the P-type thermoelectric element 11, and a second electrode part 13 connecting a lower end of the N-type thermoelectric element 12 and a lower end of the P-type thermoelectric element 11.

The P-type thermoelectric element 11 may be formed of an organic material, and may be easily formed in units of micrometers (μm) on a substrate 15.

The P-type thermoelectric element 11 may be formed of a conductive polymer material, and, the P-type thermoelectric element 11 may be formed of PEDOT:PSS to have enhanced conductivity and facilitate adjustment of a thickness thereof

The substrate 15 may be formed of a flexible material, the P-type thermoelectric element 11 may be formed in units of micrometers (μm) on a substrate 15, and thus, the thermoelectric module 10 may be lightweight and flexible on the whole.

The plurality of P-type thermoelectric elements 11 may be attached to the substrate 15, and may be positioned to be parallel to each other.

The P-type thermoelectric element 11 may be formed of an organic material configured to implement high performance, but the N-type thermoelectric element 12 does not have an organic material configured to perform high amount performance, and thus, the N-type thermoelectric element 12 may be formed of a metal including nickel (Ni), or the like.

The plurality of N-type thermoelectric elements 12 may be disposed to be parallel between the plurality of P-type thermoelectric elements 11.

The first electrode part 13 may be prepared at an upper end of the N-type thermoelectric element 12 and connected to the upper end of the P-type thermoelectric element 11. According to various exemplary embodiments, the first electrode part 13 may be formed of the same metal as that of the N-type thermoelectric element 12.

The second electrode part 14 may be prepared at a lower end of the N-type thermoelectric element 12 and connected to a lower end of the P-type thermoelectric element 11. According to various exemplary embodiments, the second electrode part 14 may be formed of the same metal as that of the N-type thermoelectric element 12.

According to various exemplary embodiments, the first electrode part 13 and the second electrode part 14 may be formed as the same body with respect to the N-type thermoelectric element 12. The first electrode part 13 may extend from the upper end of the N-type thermoelectric element 12 in one direction so as to be connected to the upper end of the adjacent P-type thermoelectric element 11 at a first side, and the second electrode part 14 may extend from a lower end of the N-type thermoelectric element 12 in a second direction to be connected to a lower end of the adjacent P-type thermoelectric element 11 at a second side. For example, the first electrode part 13 and the second electrode part 14 may extend from the upper end and the lower end of the N-type thermoelectric element 12 in the mutually opposite directions.

According to another exemplary embodiment, the first electrode part 13 and the second electrode part 14 may be independently formed with respect to the N-type thermoelectric element 12, and may be connected to the upper end and the lower end of the N-type thermoelectric element 12 through an adhesive or soldering.

A conductive glue 16 may be interposed between the upper end of the P-type thermoelectric element 11 and the first electrode part 13 to adhere the upper end of the P-type thermoelectric element 11 and the first electrode part 13, and the conductive glue 16 may be interposed between the lower end of the P-type thermoelectric element 11 and the second electrode part 14 to adhere the lower end of the P-type thermoelectric element 11 and the second electrode part 14. Through the conductive glue 16, electrical contact characteristics between the P-type thermoelectric element 11 and the electrode parts 13 and 14 may be enhanced.

Here, the conductive glue 16 may be formed of metal paste or a metal epoxy including gold (Au), platinum (Pt), silver (Ag), and nickel (Ni). The conductive glue 16 may be applied not to exceed a half of a contact area between the first and second electrode parts 13 and 14 and the P-type thermoelectric element 11 in consideration of spreading characteristics thereof.

Meanwhile, the P-type thermoelectric element 11 and the N-type thermoelectric element 12 may have different areas to enhance thermoelectric power generation performance.

As the P-type thermoelectric element 11 is formed to have an area greater than that of the N-type thermoelectric element 12, electric resistance may be increased to increase conductivity, and thus, a temperature difference between a hot side and a cold side may be stably maintained to enhance thermoelectric power generation performance of the thermoelectric module 10.

The area of the N-type thermoelectric element 11 and the area of the P-type thermoelectric element 12 may be in the ratio of 1:16 to 300.

More the area of the N-type thermoelectric element 11 and the area of the P-type thermoelectric element 12 may be in the ratio of 1:150 to 270.

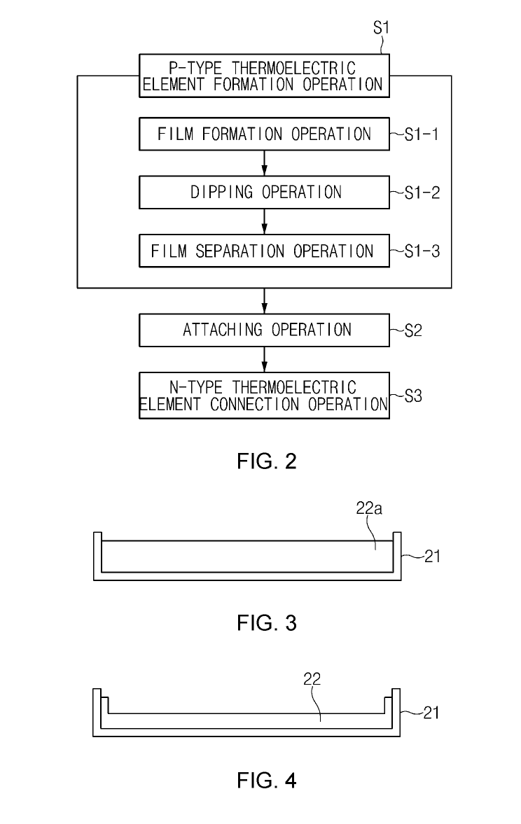

Referring to FIG. 2, a method for manufacturing a thermoelectric module according to various exemplary embodiments may include: a P-type thermoelectric element formation operation (S1) of forming a P-type thermoelectric element 11 in the form of a polymer film by drying a conductive polymer solution, an attaching operation (S2) of attaching a plurality of P-type thermoelectric elements 11 to a substrate 15, and an N-type thermoelectric element connection operation (S3) of connecting N-type thermoelectric elements 12 formed of a metal in series between the plurality of P-type thermoelectric elements 11.

The P-type thermoelectric element formation operation (S1) may include a film formation operation (S1-1), a dipping operation (S1-2), and a film separation operation (S1-3).

In the film formation operation (S1-1), a container 21 may be filled with a PEDOT:PSS solution 22a as illustrated in FIG. 3, and subsequently dried at a temperature ranging from room temperature to a temperature lower than 110° C. to form a PEDOT:PSS film 22 as illustrated in FIG. 4. Here, the PEDOT:PSS solution 22a may be a solution from which an impurity has been removed by an aqueous solution filter. 1 to 2 wt % of PEDOT:PSS may generally be dispersed in water. PEDOT:PSS in a powder state may have high viscosity but it has low conductivity. Thus, the PEDOT:PSS solution 22a may be used.

The container 21 may be formed of a material having release characteristics including Teflon, and may also be formed of a material having chemical resistance with a smooth surface.

Also, before the PEDOT:PSS solution 22a is dried, the PEDOT:PSS solution 22a may be repeatedly applied to adjust a thickness of the PEDOT:PSS film 22.

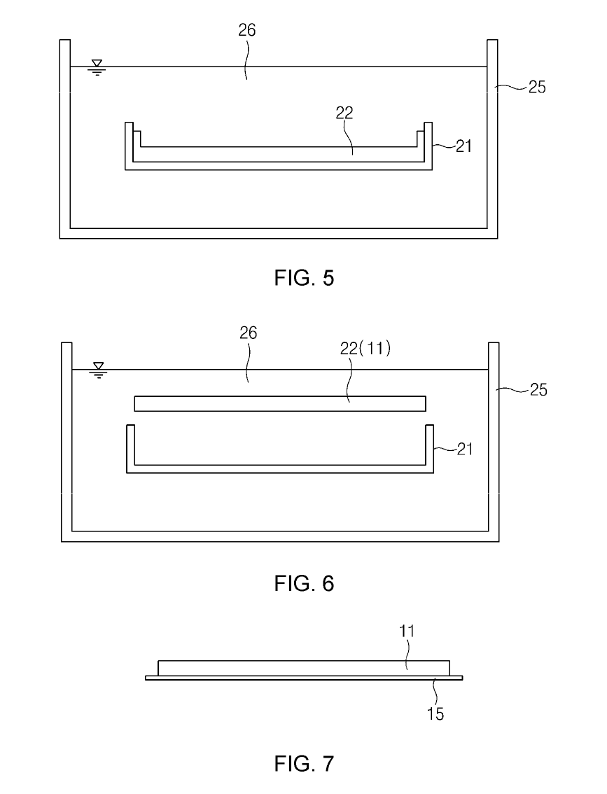

In the dipping operation (S1-2), as illustrated in FIG. 5, the PEDOT:PSS film 22 dried within the container 21 may be dipped together with the container 21 to an organic solvent 26 within a dipping container 25 (S1-2). In this manner, by dipping the PEDOT:PSS film 22 together with the container 21, damage to the PEDOT:PSS film 22 may be prevented. Here, the organic solvent may be ethylene glycol (EG) or dimethyl sulfoxide (DMSO).

Through the dipping, the PEDOT:PSS film 22 may be separated from the container 21. Also, as a portion of PSS of the PEDOT:PSS film 22 is removed through the dipping (dedoping), conductivity of the PEDOT:PSS film 22 may be enhanced.

In the film separation operation (S1-3), as illustrated in FIG. 6, edges of the PEDOT:PSS film 22 may be appropriately cut out, and the PEDOT:PSS film 22 may subsequently be separated from the container 21, thus forming the P-type thermoelectric element 11 (please refer to FIG. 7) in the form of a film.

In the attaching operation (S2), as illustrated in FIG. 7, the P-type thermoelectric element 11 formed through the P-type thermoelectric element formation operation (S1) as described above may be mounted on a substrate 15 and subsequently dried under a high temperature atmosphere (in an oven at a temperature of 130° C.) to allow the P-type thermoelectric element 11 having a thickness ranging from a few to hundreds of micrometers to be stably attached to the substrate 15.

In this manner, as the P-type thermoelectric element 11 in the form of a polymer film is formed, a thickness thereof may be implemented in units of a few to hundreds of micrometers, and thus, a temperature difference in a vertical direction (a temperature difference between a hot side and a cold side), as well as a temperature difference in a horizontal direction, may be effectively made.

In the N-type thermoelectric element connection operation (S3), N-type thermoelectric elements 12 formed of a metal may be connected in series between the plurality of P-type thermoelectric elements 11.

As described above, according to exemplary embodiments of the present invention, since the manufacturing process is simple, manufacturing cost may be reduced, and since the P-type thermoelectric element is formed in the form of a polymer film by drying a polymer solution such as PEDOT:PSS, or the like, a thickness thereof may be implemented in units of a few to hundreds of micrometers. Thus, since a temperature difference in a vertical direction (a temperature difference between a hot side and a cold side), as well as a temperature difference in a horizontal direction, is effectively made, thermoelectric power generation performance may be enhanced.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the claims appended hereto and their equivalents.

What is claimed is:

1. A thermoelectric module comprising:
a plurality of P-type thermoelectric elements formed of an organic material;
a plurality of N-type thermoelectric elements positioned in parallel between the plurality of P-type thermoelectric elements and formed of a metal;
a first electrode part connecting an upper end of each of the plurality of N-type thermoelectric elements and an upper end of each of the plurality of P-type thermoelectric elements; and
a second electrode part connecting a lower end of each of the N-type thermoelectric elements and a lower end of each of the plurality of P-type thermoelectric elements,
wherein the first electrode part, the second electrode part, and the plurality of N-type thermoelectric elements are formed of a metal.

2. The thermoelectric module according to claim 1, wherein the plurality of P-type thermoelectric elements are formed of a conductive polymer material.

3. The thermoelectric module according to claim 1, wherein the plurality of P-type thermoelectric elements are formed of PEDOT:PSS.

4. The thermoelectric module according to claim 1, wherein the first electrode part, the second electrode part, and the plurality of N-type thermoelectric elements are formed as a same body.

5. The thermoelectric module according to claim 1, wherein the upper end of each of the plurality of N-type thermoelectric elements and the first electrode part are adhered through a conductive glue interposed therebetween, and the lower end of each of the N-type thermoelectric elements and the second electrode part are adhered through the conductive glue interposed therebetween.

6. The thermoelectric module according to claim 1, wherein the plurality of P-type thermoelectric elements and the plurality of N-type thermoelectric elements have different areas.

7. The thermoelectric module according to claim 1, wherein an area of each of the plurality of P-type thermoelectric elements is greater than an area of each of the plurality of N-type thermoelectric elements.

8. The thermoelectric module according to claim 1, wherein an area of each of the plurality of N-type thermoelectric elements and an area of each of each of the plurality of P-type thermoelectric elements are in a ratio of 1:16 to 300.

9. The thermoelectric module according to claim 1, wherein an area of each of the plurality of N-type thermoelectric elements and an area of each of the plurality of P-type thermoelectric elements are in a ratio of 1:150 to 270.

10. A method for manufacturing a thermoelectric module, the method comprising:
a P-type thermoelectric element formation operation of forming a P-type thermoelectric element in a form of a polymer film by drying a conductive polymer solution;
an attaching operation of attaching a plurality of P-type thermoelectric elements to a substrate; and
an N-type thermoelectric element connection operation of connecting N-type thermoelectric elements formed of a metal in series between the plurality of P-type thermoelectric elements.

11. The method according to claim 10, wherein the P-type thermoelectric element formation operation includes:
a film formation operation of filling a container with a PEDOT:PSS solution and drying the PEDOT:PSS solution to form a PEDOT:PSS film;
a dipping operation of dipping the PEDOT:PSS film in an organic solvent; and
a film separation operation of separating the PEDOT:PSS film from the container to form a P-type thermoelectric element.

12. The method according to claim 11, wherein, in the dipping operation, the PEDOT:PSS film is dipped together with the container in the organic solvent, and the organic solvent is ethylene glycol (EG) or dimehtyl sulfoxide (DMSO).

13. The method according to claim 11, wherein, in the film formation operation, a thickness of each of the plurality of P-type thermoelectric elements is adjusted by repeatedly filling the container with the PEDOT:PSS solution before the PEDOT:PSS solution is dried.

14. The method according to claim 10, wherein, in the attaching operation, the plurality of P-type thermoelectric elements are mounted on the substrate and dried under a temperature higher than a predetermined temperature to allow the plurality of P-type thermoelectric elements to be attached to the substrate.
